(19) United States
(12) Patent Application Publication
(10) Pub. No.: US 2025/0081827 A1
(43) Pub. Date: Mar. 6, 2025

(54) Display Device

(71) Applicant: LG Display Co., Ltd., Seoul (KR)

(72) Inventor: JaeHyun Park, Paju-si (KR)

(21) Appl. No.: 18/742,243

(22) Filed: Jun. 13, 2024

(30) Foreign Application Priority Data
Sep. 4, 2023 (KR) 10-2023-0116992

(51) Int. Cl. H10K 59/80; H10K 59/40

(52) U.S. Cl. CPC H10K 59/879; H10K 59/40

(57) ABSTRACT

A display device includes a pixel including sub pixels representing different colors. Each of the sub pixels includes a first light emitting diode and a second light emitting diode. A touch sensor unit is on the first light emitting diode and the second light emitting diode of a sub pixel and the touch sensor unit includes first openings overlapping an emission area of the first light emitting diode. First lenses are disposed within the first openings of the touch sensor unit and have a viewing angle of a first value and overlap the emission area of the first light emitting diode of the sub pixel. A second lens is on the touch sensor unit and has a viewing angle of a second value that is greater than the first value and the second lens overlaps an emission area of the second light emitting diode of the sub pixel.

### CROSS-REFERENCE TO RELATED APPLICATION

This application claims the priority of Republic of Korea Patent Application No. 10-2023-0116992 filed on Sep. 4, 2023, which is hereby incorporated by reference in its entirety.

### BACKGROUND

### Field

The present disclosure relates to a display device, and more particularly to a display device in which a viewing angle is controllable.

### Description of the Related Art

As technology in modern society develops, display devices are used in various ways to provide information to users. The display devices include not only electronic signs which simply transmit visual information in one direction, but also various electronic devices which require a higher level of technology to check user's input and provide information in response to the checked input.

For example, a display device is included in a vehicle to provide various information to a driver and passengers of the vehicle. However, the display device of the vehicle needs to appropriately display contents without interrupting the operation of the vehicle. For example, the display device needs to limit the display of the contents which may reduce the concentration on the driving while the vehicle is in operation.

### SUMMARY

An object to be achieved by the present disclosure is to provide a display device in which a viewing angle can be selectively controlled.

Another object to be achieved by the present disclosure is to provide a display device which minimizes or at least reduces a process error of a process of placing a plurality of lenses to control a viewing angle.

Still another object to be achieved by the present disclosure is to provide a display device with an improved luminous efficiency.

Still another object to be achieved by the present disclosure is to provide a display device with an improved vertical luminance.

Still another object to be achieved by the present disclosure is to provide a display device with an improved lifespan.

Objects of the present disclosure are not limited to the above-mentioned objects, and other objects, which are not mentioned above, can be clearly understood by those skilled in the art from the following descriptions.

In one embodiment, a display device comprises: a pixel on a substrate, the pixel including a plurality of sub pixels representing different colors, each of the plurality of sub pixels including a first light emitting diode and a second light emitting diode; a touch sensor unit on the first light emitting diode and the second light emitting diode of a sub pixel of the plurality of sub pixels, the touch sensor unit including a plurality of first openings overlapping an emission area of the first light emitting diode of the sub pixel; a plurality of first lenses disposed within the plurality of first openings of the touch sensor unit, the plurality of first lenses having a viewing angle of a first value and each of the plurality of first lenses overlapping the emission area of the first light emitting diode of the sub pixel; and a second lens on the touch sensor unit, the second lens has a viewing angle of a second value that is greater than the first value and the second lens overlapping an emission area of the second light emitting diode of the sub pixel.

In one embodiment, a display device comprises: a substrate; a sub-pixel on the substrate, the sub-pixel including a first light emitting diode; a touch sensor including a plurality of first openings that overlap an emission area of the first light emitting diode; and a plurality of first lenses on the touch sensor, each first lens from the plurality of first lenses disposed within a corresponding first opening from the plurality of first openings and in contact with a portion of the touch sensor within the corresponding first opening.

Other detailed matters of the exemplary embodiments are included in the detailed description and the drawings.

In the display device according to the present disclosure, the viewing angle may be selectively controlled.

In the display device according to the present disclosure, a degree of freedom of design of a plurality of lenses may be improved by minimizing or at least reducing a process error.

In the display device according to the present disclosure, sizes of the plurality of lenses are reduced to be disposed so that the luminous efficiency may be improved.

The display device according to the present disclosure is configured to emit light emitted from the light emitting diode to a front direction of the display device to improve a vertical luminance.

In the display device according to the present disclosure, the luminance is improved so that the lifespan may also be improved.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplary view of a display device according to an exemplary embodiment of the present disclosure;

FIG. 2 is a functional block diagram of a display device according to an exemplary embodiment of the present disclosure;

FIG. 3 is a circuit diagram illustrating an example of a pixel circuit of a display device according to an exemplary embodiment of the present disclosure;

FIG. 4 is an enlarged plan view illustrating placement of a lens included in one pixel of a display device according to an exemplary embodiment of the present disclosure;

FIG. 5 is a cross-sectional view taken along the line A-A′ of FIG. 4 according to an exemplary embodiment of the present disclosure;

FIG. 6 is a cross-sectional view taken along the line B-B′ of FIG. 4 according to an exemplary embodiment of the present disclosure;

FIGS. 7A to 7G are process diagrams for explaining a manufacturing process of a display device according to an exemplary embodiment of the present disclosure;

FIG. 8 is an enlarged plan view of a display device according to another exemplary embodiment of the present disclosure;

FIG. 9 is a cross-sectional view of a display device according to still another exemplary embodiment of the present disclosure; and

FIG. 10 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

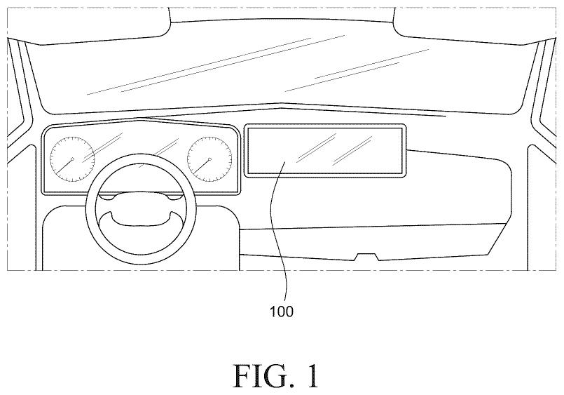

FIG. 1 is an exemplary view of a display device according to an exemplary embodiment of the present disclosure.

The display device 100 may be disposed in at least a part of a dashboard of a vehicle. The dashboard of the vehicle includes a configuration disposed in front surfaces of front seats (for example, a driver seat and a front passenger seat) of the vehicle. For example, on the dashboard of the vehicle, an input configuration for manipulating various functions (for example, an air-conditioner, an audio system, or a navigation system) in the vehicle may be disposed.

In the exemplary embodiment, the display device 100 is disposed on the dashboard of the vehicle to operate as an input unit which manipulates at least a part of various functions of the vehicle. The display device 100 may provide various information related to the vehicle, for example, operation information of the vehicle (for example, a current speed of the vehicle, a remaining fuel amount, or a mileage) or information about parts of the vehicle (for example, a damage level of a vehicle tire).

In an exemplary embodiment, the display device 100 may be disposed across the driver seat and the front passenger seat disposed in the front seats of the vehicle. A user of the display device 100 may include a driver of the vehicle and a passenger riding on the front passenger seat. Both the vehicle driver and the passenger use the display device 100.

In the exemplary embodiment, only a part of the display device 100 may be illustrated in FIG. 1. The display device 100 illustrated in FIG. 1 may illustrate a display panel, among various configurations included in the display device 100. Specifically, for example, the display device 100 illustrated in FIG. 1 may illustrate an active area and at least a part of a non-active area of the display panel. Among the configurations of the display device 100, configurations other than the parts illustrated in FIG. 1 may be mounted inside the vehicle (or on at least a part of the inside of the vehicle).

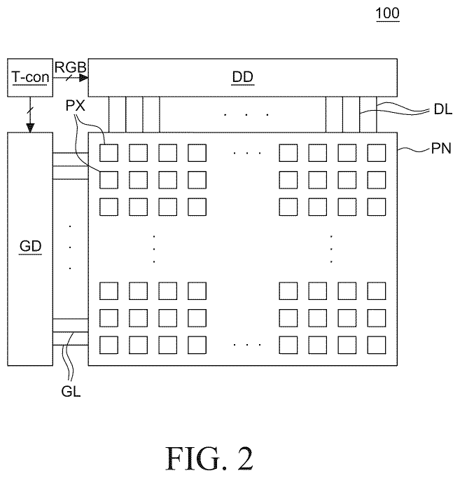

FIG. 2 is a functional block diagram of a display device according to an exemplary embodiment of the present disclosure.

The electroluminescent display device may be applied to the display device according to the exemplary embodiment of the present disclosure. The electroluminescent display device may use an organic light emitting diode (OLED) display device, a quantum dot light emitting diode display device, or an inorganic light emitting diode display device.

Referring to FIG. 2, the display device 100 includes a display panel PN, a data driving circuit DD, a gate driving circuit GD, and a timing controller T-con.

In the exemplary embodiment, the display panel PN may generate images to be provided to the user. For example, the display panel PN may generate and display images to be provided to the user through a plurality of pixels PX in which the pixel circuits are disposed.

The data driving circuit DD, the gate driving circuit GD, and the timing controller T-con may provide signals for operations of the pixels PX through signal lines. The signal lines may include data lines DL and gate lines GL, for example.

In some cases, the display device may further include a power unit. In this case, a signal for an operation of the pixel PX may be supplied through the power line which connects the power unit and the display panel PN. According to the exemplary embodiment, the power unit may supply a power to the data driving circuit DD and the gate driving circuit GD. The data driving circuit DD and the gate driving circuit GD may be driven based on the power supplied from the power unit.

For example, the data driving circuit DD may apply a data signal to each pixel PX through the data lines DL. The gate driving circuit GD may apply a gate signal to each pixel PX through the gate lines GL. The power unit may supply a power voltage to each pixel PX through the power voltage supply lines.

The timing controller T-con may control the data driving circuit DD and the gate driving circuit GD. For example, the timing controller T-con rearranges digital video data input from the outside in accordance with a resolution of the display panel PN to supply the digital video data to the data driving circuit DD.

The data driving circuit DD converts digital video data input from the timing controller T-con into an analog data voltage based on the data control signal to supply the converted analog data voltage to the plurality of data lines.

The gate driving circuit GD may generate a scan signal and an emission signal (or an emission control signal) based on the gate control signal. The gate driving circuit GD may include a scan driver and an emission signal driver. The scan driver generates a scan signal in a row sequential manner to drive at least one scan line connected to each pixel row to supply the scan signal to the scan lines. The emission signal driver generates an emission signal in a row sequential manner to drive at least one emission signal line connected to each pixel row to supply the emission signal to the emission signal lines.

According to the exemplary embodiment, the gate driving circuit GD may be disposed in the display panel PN in a gate-driver in panel (GIP) manner. For example, the gate driving circuit GD is divided into a plurality of circuits to be disposed on at least two side surfaces of the display panel PN.

The display panel PN may include an active area and a non-active area.

The active area may include a plurality of pixels PX. In the pixel PX, a plurality of data lines (for example, data lines DL of FIG. 2) and a plurality of gate lines (for example, gate lines GL of FIG. 2) intersect and sub pixels may be disposed in each intersecting area. Each sub pixel included in one pixel PX may emit different color light. For example, the pixel PX uses three sub pixels to implement blue, red, and green. However, this is not limited thereto and in some cases, the pixel PX may further include a sub pixel for further implementing a specific color (for example, white).

In the pixel PX, an area which implements blue may be referred to as a blue sub pixel, an area which implements red may be referred to as a red sub pixel, and an area which implements green may be referred to as a green sub pixel.

In the exemplary embodiment, the pixel PX may include a plurality of sub pixels. Each of the plurality of sub pixels may be divided into a first lens area and a second lens area which provide different viewing angles. For example, one pixel PX may include a first lens area which supplies light in a first range to form a first viewing angle and a second lens area which supplies light in a second range to form a second viewing angle. The first range may be wider than the second range.

The non-active area may be disposed along the circumference of the active area. Various components for driving the pixel circuit disposed in the pixel PX may be disposed in the non-active area. For example, at least a part of the gate driving circuit GD may be disposed in the non-active area. The non-active area may be referred to as a bezel area.

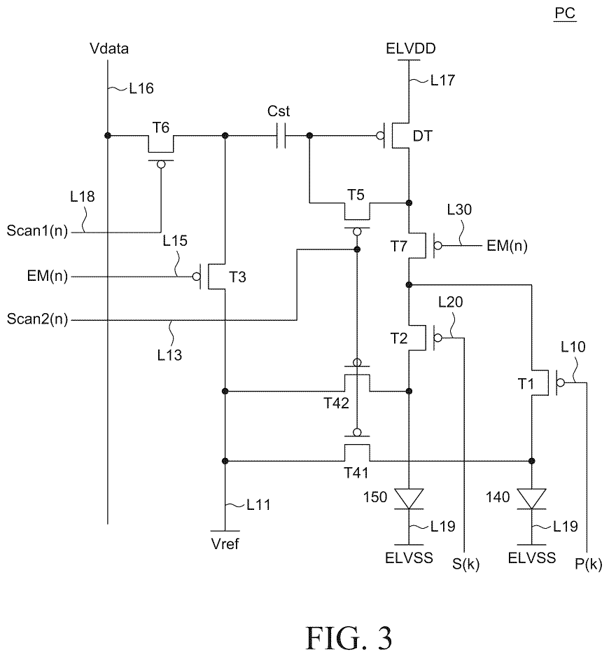

FIG. 3 is a circuit diagram illustrating an example of a pixel circuit of a display device according to an exemplary embodiment of the present disclosure. The pixel PX may include a plurality of sub pixels which represents different colors and pixel circuits PC corresponding to the plurality of sub pixels. FIG. 3 illustrates an example of a pixel circuit PC for one sub pixel disposed in the pixel PX.

Referring to FIG. 3, the pixel circuit PC may include nine transistors and one capacitor.

The pixel circuit PC may include a first transistor T1, a second transistor T2, a third transistor T3, a 4-1-th transistor T41, a 4-2-th transistor T42, a fifth transistor T5, a sixth transistor T6, a seventh transistor T7, a driving transistor DT, and a capacitor Cst.

At least some of the nine transistors included in the pixel circuit PC may be an n-type transistor or a p-type transistor. In the case of the p-type transistor, a low-level voltage of each driving signal may refer to a voltage which turns on the TFT and a high-level voltage of each driving signal may refer to a voltage which turns off the TFT.

Here, the low-level voltage may correspond to a predetermined voltage which is lower than the high level. For example, the low-level voltage may include a voltage corresponding to a range of −8 V to −12 V. The high-level voltage may correspond to a predetermined voltage which is higher than the low-level voltage. For example, the high-level voltage may include a voltage corresponding to the range of 12 V to 16 V. According to the exemplary embodiment, the low-level voltage may be referred to as a first voltage and the high-level voltage may be referred to as a second voltage. In this case, the first voltage may be lower than the second voltage. However, the ranges of the low-level voltage and the high-level voltage are illustrative, but are not limited thereto.

Here, a first electrode or a second electrode of the transistor to be described below may refer to a source electrode or a drain electrode. However, the terminologies of the first electrode and the second electrode are just terminologies for distinguishing the electrodes, but do not limit what corresponds to each electrode. Further, in each electrode, the first electrode may not refer to the same electrode. For example, a first electrode of the first transistor T1 may refer to a source electrode of the first transistor T1 and a first electrode of the sixth transistor T6 may refer to a drain electrode of the sixth transistor T6.

In the exemplary embodiment, the driving transistor DT may be connected to the first transistor T1 connected to the first light emitting diode 140 and the second transistor T2 connected to the second light emitting diode 150. For example, the second electrode of the driving transistor DT may be connected to the first transistor T1 and the second transistor T2.

In the exemplary embodiment, the driving transistor DT may be connected to a first power line L17 which supplies a high potential power voltage ELVDD. For example, the first electrode of the driving transistor DT may be connected to the first power line L17. When the driving transistor DT is turned on, the high potential power voltage ELVDD supplied through the first power line L17 may be transmitted from the first electrode to the second electrode of the driving transistor DT.

In the exemplary embodiment, the first transistor T1 may be connected to at least one of the first light emitting diode 140, the second transistor T2, the 4-1-th transistor T41, and the seventh transistor T7.

For example, the first electrode of the first transistor T1 may be connected to at least one of the second transistor T2 and the seventh transistor T7. The seventh transistor T7 may be connected to the driving transistor DT and the fifth transistor T5. The second electrode of the first transistor T1 may be connected to at least one of the first light emitting diode 140 and the 4-1-th transistor T41. The gate electrode of the first transistor T1 may be connected to a first control line L10. The first transistor T1 may be turned on or off by a first control signal P(k) supplied through the first control line L10. When the first transistor T1 is turned on, the voltage through the driving transistor DT and the seventh transistor T7 may be input to the first light emitting diode 140 (for example, an anode electrode of the first light emitting diode 140).

Here, the first control signal P(k) may include a k-th first control signal which is supplied to a k-th column in response to the pixel circuit PC which is disposed in a k-th (k is a positive integer) column. The first control signal P(k) is supplied by a mode controller (or a mode control circuit) during a first mode (e.g., a privacy mode) and may control the driving (or emission) of the first light emitting diode 140 in which the first lens is disposed. Thus, during the first mode the first light emitting diode 140 emits light without the second light emitting diode 150 emitting light during the first mode.

In the exemplary embodiment, the second transistor T2 may be connected to at least one of the second light emitting diode 150, the first transistor T2, the 4-2-th transistor T42, and the seventh transistor T7.

For example, the first electrode of the second transistor T2 may be connected to at least one of the first transistor T1 and the seventh transistor T7. The second electrode of the second transistor T2 may be connected to at least one of the 4-2-th transistor T42 and the second light emitting diode 150. The seventh transistor T7 may be connected to the driving transistor DT and the fifth transistor T5. The gate electrode of the second transistor T2 may be connected to a second control line L20. The second transistor T2 may be turned on or off by a second control signal S(k) supplied through the second control line L20. When the second transistor T2 is turned on, the voltage through the driving transistor DT and the seventh transistor T7 may be input to the second light emitting diode 150 (for example, an anode electrode of the second light emitting diode 150).

Here, the second control signal S(k) may include a k-th second control signal which is supplied to a k-th column in response to the pixel circuit PC which is disposed in a k-th (k is a positive integer) column. The second control signal S(k) is supplied by the mode controller (or the mode control circuit) during a second mode (e.g., a sharing mode) and may control the driving (or emission) of the second light emitting diode 150 in which the second lens is disposed. Thus, during the second mode the second light emitting diode 150 emits light without the first light emitting diode 140 emitting light during the second mode.

In one exemplary embodiment, the first lens may be disposed on the first light emitting diode 140. A viewing angle of the area in which the first light emitting diode 140 is disposed may correspond to a first value by the first lens. For example, the viewing angle of the area in which the first light emitting diode 140 is disposed may be equal to or smaller than the first value. The second lens may be disposed on the second light emitting diode 150. A viewing angle of the area in which the second light emitting diode 150 is disposed may correspond to a second value by the second lens. The second value may be larger than the first value. For example, the viewing angle of the area in which the second light emitting diode 150 is disposed may be equal to or larger than the second value.

In the exemplary embodiment, the area in which the first light emitting diode 140 of the pixel circuit PC is disposed may have a viewing angle of a first value to supply light to a range corresponding to the front passenger seat. The area in which the second light emitting diode 150 is disposed may have a viewing angle of a second value to supply light to a range corresponding to the front passenger seat and the driver seat next to the front passenger seat.

In the exemplary embodiment, the third transistor T3 may be connected to at least one of a 4-1-th transistor T41, a 4-2-th transistor T42, a sixth transistor T6, and a capacitor Cst.

For example, the first electrode of the third transistor T3 may be connected to the sixth transistor T6 and the capacitor Cst. The second electrode of the third transistor T3 may be connected to the 4-1-th transistor T41 and the 4-2-th transistor T42. The gate electrode of the third transistor T3 may be connected to the emission signal line L15 which supplies the emission signal EM(n). The emission signal EM(n) may correspond to an n-th emission signal EM(n) supplied to an n-th row as the pixel circuit PC is disposed in an n-th (n is a positive integer) pixel row. The third transistor T3 may be turned on or off by the emission signal EM(n). The second electrode of the third transistor T3 may be connected to the reference voltage line L11 which supplies a reference voltage Vref, for example, the second power line.

In the exemplary embodiment, the 4-1-th transistor T41 may be connected to at least one of the first transistor T1, the third transistor T3, and the first light emitting diode 140.

For example, the first electrode of the 4-1-th transistor T41 may be connected to the third transistor T3. The second electrode of the 4-1-th transistor T41 may be connected to the first transistor T1 and the first light emitting diode 140. The gate electrode of the 4-1-th transistor T41 may be connected to an n-th second scan line L13. Therefore, the 4-1-th transistor T41 may be supplied with an n-th second scan signal Scan2(n) and may be turned on or off by the n-th second scan signal Scan2(n).

In the exemplary embodiment, the 4-2-th transistor T42 may be connected to at least one of the second transistor T2, the third transistor T3, and the second light emitting diode 150.

For example, the first electrode of the 4-2-th transistor T42 may be connected to the third transistor T3. The second electrode of the 4-2-th transistor T42 may be connected to the second transistor T2 and the second light emitting diode 150. The gate electrode of the 4-2-th transistor T42 may be connected to an n-th second scan line L13. Therefore, the 4-2-th transistor T42 may be supplied with an n-th second scan signal Scan2(n) and may be turned on or off by the n-th second scan signal Scan2(n).

In the exemplary embodiment, the fifth transistor T5 may be connected to at least one of the driving transistor DT, the 4-1-th transistor T41, the 4-2-th transistor T42, the capacitor Cst, and the seventh transistor T7.

For example, the first electrode of the fifth transistor T5 may be connected to the driving transistor DT and the capacitor Cst. The second electrode of the fifth transistor T5 may be connected to the driving transistor DT and the seventh transistor T7. The gate electrode of the fifth transistor T5 may be connected to the n-th second scan line L13 which supplies the second scan signal Scan2(n) in the n-th row. The fifth transistor T5 may be supplied with the n-th second scan signal Scan2(n) and may be turned on or off by the n-th second scan signal Scan2(n).

According to the exemplary embodiment, the n-th first scan line L18 may supply the n-th first scan signal. In this case, the n-th first scan signal may be supplied to the gate electrode of the sixth transistor T6. The n-th second scan line L13 may supply the n-th second scan signal. In this case, the n-th second scan signal may be supplied to gate electrodes of the 4-1-th transistor T41, the 4-2-th transistor T42, and the fifth transistor T5.

In the exemplary embodiment, the sixth transistor T6 may be connected to at least one of the third transistor T3 and the capacitor Cst.

For example, the first electrode of the sixth transistor T6 may be connected to the third transistor T3 and the capacitor Cst. The second electrode of the sixth transistor T6 may be connected to the data line L16 which supplies a data voltage Vdata. The gate electrode of the sixth transistor T6 may be connected to the n-th first scan line L18 which supplies the n-th first scan signal Scan1(n). The sixth transistor T6 may be supplied with an n-th first scan signal Scan1(n) and may be turned on or off by the n-th first scan signal Scan1(n). When the sixth transistor T6 is turned on, the data voltage Vdata may be transmitted from the second electrode to the first electrode.

In the exemplary embodiment, the seventh transistor T7 may be connected to at least one of the first transistor T1, the second transistor T2, the fifth transistor T5, and the driving transistor DT.

For example, the first electrode of the seventh transistor T7 may be connected to at least one of the fifth transistor T5 and the driving transistor DT. The second electrode of the seventh transistor T7 may be connected to at least one of the first transistor T1 and the second transistor T2. The gate electrode of the seventh transistor T7 may be connected to the emission signal line L30 which supplies the emission signal EM(n). The seventh transistor T7 may be turned on or off based on the emission signal EM(n). When the seventh transistor is turned on, a voltage (or a current) may be supplied from the first electrode to the second electrode of the seventh transistor T7.

In the exemplary embodiment, the first light emitting diode 140 and/or the second light emitting diode 150 may be connected to the third power line L19 which supplies a low potential power voltage ELVSS. For example, the cathode electrode of the first light emitting diode 140 and the cathode electrode of the second light emitting diode 150 are connected to the third power line L19 to be supplied with the low potential power voltage ELVSS.

According to the exemplary embodiment, the low potential power voltage may be a ground voltage (for example, 0 V). For example, the cathode electrode of the first light emitting diode 140 and the cathode electrode of the second light emitting diode 150 may be supplied with a voltage corresponding to the ground voltage, but are not limited thereto.

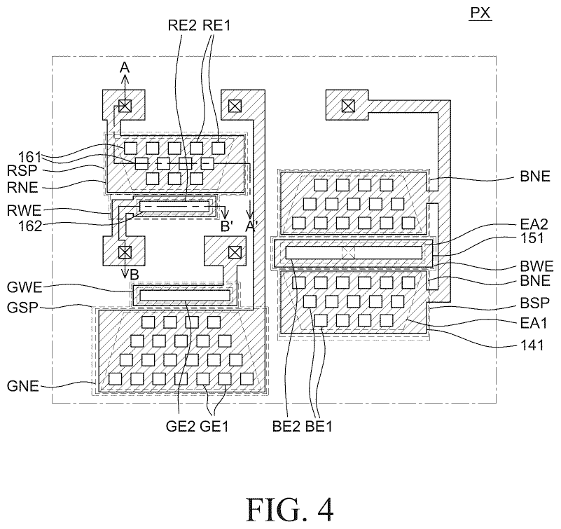

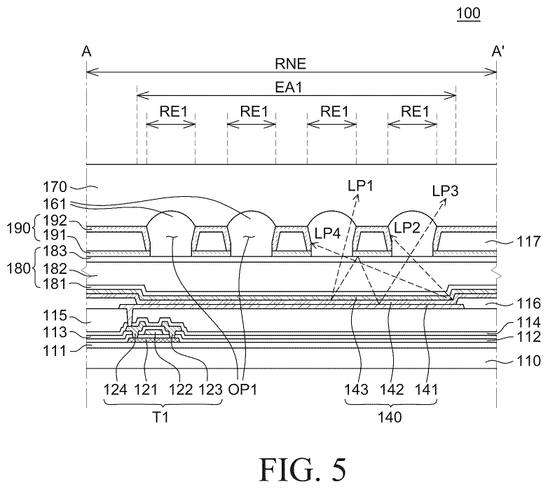

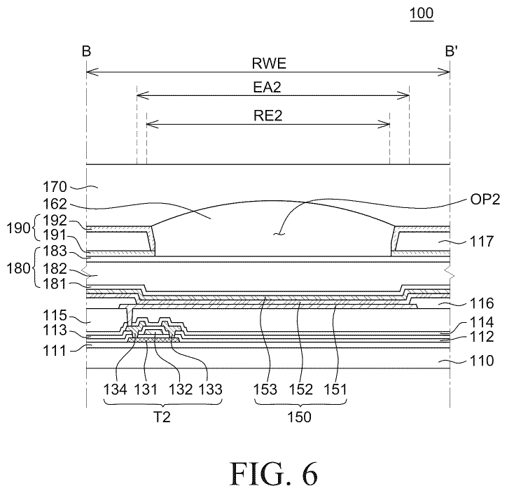

FIG. 4 is an enlarged plan view illustrating the placement of a lens included in one pixel of a display device according to an exemplary embodiment of the present disclosure. FIG. 5 is a cross-sectional view taken along the line A-A′ of FIG. 4 according to an exemplary embodiment of the present disclosure. FIG. 6 is a cross-sectional view taken along B-B′ of FIG. 4 according to an exemplary embodiment of the present disclosure. FIG. 4 illustrates a plane of a pixel PX when three sub pixels RSP, GSP, and BSP are disposed in one pixel PX. FIG. 5 illustrates a cross-section taken along the line A-A′ of FIG. 4 and FIG. 6 illustrates a cross-section taken along the line B-B′ of FIG. 4. However, even though in FIGS. 5 and 6, for the convenience of description, only an area corresponding to a first lens area RNE and a second lens area RWE of the red sub pixel RSP, among the plurality of sub pixels RSP, GSP, and BSP, is illustrated, the other sub pixels GSP and BSP may also be formed with the same configuration.

First, referring to FIG. 4, the pixel PX may include a plurality of sub pixels RSP, GSP, and BSP which represents different colors. For example, the pixel PX may include a blue sub pixel BSP which implements blue light, a red sub pixel RSP which implements red light, and a green sub pixel GSP which implements green light. According to the exemplary embodiment, the blue sub pixel BSP may correspond to a first sub pixel, the red sub pixel RSP may correspond to a second sub pixel, and the green sub pixel GSP may correspond to a third sub pixel. The pixel circuit PC may correspond to each of the sub pixels RSP, GSP, and BSP. A corresponding pixel circuit PC (for example, the pixel circuit of FIG. 3) may be disposed in each of the sub pixels RSP, GSP, and BSP.

The sub pixels RSP, GSP, and BSP may include first lens areas RNE, GNE, and BNE and second lens areas BWE, RWE, and GWE which provide different viewing angles, respectively.

The second lens areas RWE, GWE, and BWE of the sub pixels RSP, GSP, and BSP may operate independently from the first lens areas RNE, GNE, and BNE of the corresponding pixels PX. For example, in each sub pixel RSP, GSP, BSP, the first light emitting diode 140 (for example, the first light emitting diode 140 of FIG. 3) and the second light emitting diode 150 (for example, the second light emitting diode 150 of FIG. 3) may be disposed. The first light emitting diode 140 is located in the first lens areas RNE, GNE, and BNE of the corresponding sub pixels RSP, GSP, and BSP and the second light emitting diode 150 is located in the second lens areas RWE, GWE, and BWE of the corresponding sub pixels RSP, GSP, and BSP.

In one pixel PX, the first light emitting diode 140 and the second light emitting diode 150 may be disposed in every first lens area RNE, GNE, BNE and second lens areas RWE, GWE, BWE of the plurality of sub pixels RSP, GSP, and BSP.

For example, in one pixel PX, a first light emitting diode 140 disposed in the first lens area RNE of the red sub pixel RSP, and a second light emitting diode 150 disposed in the second lens area RWE of the red sub pixel RSP may be disposed. In one pixel PX, a first light emitting diode 140 disposed in the first lens area GNE of the green sub pixel GSP, and a second light emitting diode 150 disposed in the second lens area GWE of the green sub pixel GSP may be disposed. Further, in one pixel PX, a first light emitting diode 140 disposed in the first lens area BNE of the blue sub pixel BSP, and a second light emitting diode 150 disposed in the second lens area BWE of the blue sub pixel BSP may be disposed.

In the meantime, referring to FIG. 4, in the blue sub pixel BSP of one pixel PX, two first lens areas BNE may be disposed. However, in the blue sub pixel BSP of one pixel PX, only one first lens area BNE may be disposed, but is not limited thereto.

Referring to FIG. 4, in the first lens areas RNE, GNE, and BNE of the sub pixels RSP, GSP, and BSP, a plurality of first lenses 161 which overlap the emission area EA1 of the first light emitting diode 140 are disposed. In the second lens areas RWE, GWE, and BWE of the sub pixels RSP, GSP, and BSP, a second lens 162 overlaps the emission area EA2 of the second light emitting diode 150. At this time, the first lens areas RNE, GNE, and BNE may have a viewing angle of a first value and the second lens areas RWE, GWE, and BWE may have a viewing angle of a second value which is higher (e.g., greater) than the viewing angle of the first value. In the meantime, the specific placement structure of the plurality of first lenses 161 and the second lens 162 will be described below with reference to FIGS. 5 and 6 together.

Referring to FIGS. 5 and 6 together, the display device 100 according to the exemplary embodiment of the present disclosure may include a substrate 110, a buffer layer 111, a gate insulating layer 112, an interlayer insulating layer 113, a lower protection layer 114, an overcoat layer 115, a first transistor T1, a second transistor T2, a first light emitting diode 140, a second light emitting diode 150, an encapsulation member 180, a touch insulating layer 117, a touch sensor unit 190, a first lenses 161, a second lens 162, and a lens protection layer 170.

The substrate 110 may be disposed so as to support other components disposed on the substrate 110. The substrate 110 may include an insulating material. The substrate 110 may include a transparent material. For example, the substrate 110 may include glass or plastic, but is not limited thereto.

The buffer layer 111 may be located between the substrate 110 and a driving part of each sub pixel RSP, GSP, BSP. The buffer layer 111 may suppress the contamination due to the substrate 110 in a process of forming the driving part. For example, a top surface of the substrate 110 which faces the driving part of each sub pixel RSP, GSP, BSP may be covered by the buffer layer 111. The driving part of each sub pixel RSP, GSP, BSP may be disposed on the buffer layer 111.

The buffer layer 111 may include an insulating material. For example, the buffer layer 111 may include an inorganic insulating material, such as silicon oxide (SiOx) or silicon nitride (SiNx). The buffer layer 111 may have a multi-layered structure. For example, the buffer layer 111 may have a laminated structure of a film formed of silicon nitride (SiNx) and a film formed of silicon oxide (SiOx), but is not limited thereto.

The gate insulating layer 112 may be located on the buffer layer 111. The gate insulating layer 112 may extend between a semiconductor layer and a gate electrode of the transistor. For example, the gate electrodes 122 and 132 of the first transistor T1 and the second transistor T2 may be insulated from the semiconductor layers 121 and 131 of the first transistor T1 and the second transistor T2, by the gate insulating layer 112. The gate insulating layer 112 may cover the first semiconductor layer 121 and the second semiconductor layer 131 of each sub pixel RSP, GSP, BSP. The gate electrodes 122 and 132 of the first transistor T1 and the second transistor T2 may be located on the gate insulating layer 112.

The gate insulating layer 112 may include an insulating material. For example, the gate insulating layer 112 may include an inorganic insulating material, such as silicon oxide (SiO) or silicon nitride (SiN). The gate insulating layer 112 may include a material having a high permittivity. For example, the gate insulating layer 112 may include a High-K material, such as hafnium oxide (HfO). The gate insulating layer 112 may have a multi-layered structure, but is not limited thereto.

The interlayer insulating layer 113 may be located on the gate insulating layer 112. The interlayer insulating layer 113 may extend between the gate electrode and the source electrode and between the gate electrode and the drain electrode of the transistor. For example, the source electrodes 123 and 133 and the drain electrodes 124 and 134 of the first transistor T1 and the second transistor T2 may be insulated from the gate electrodes 122 and 132 by the interlayer insulating layer 113. The interlayer insulating layer 113 may cover the gate electrodes 122 and 132 of the first transistor T1 and the second transistor T2. The source electrodes 123 and 133 and the drain electrodes 124 and 134 of each sub pixel RSP, GSP, BSP may be located on the interlayer insulating layer 113. The gate insulating layer 112 and the interlayer insulating layer 113 may expose a source region and a drain region of each semiconductor layer 121, 131.

The interlayer insulating layer 113 may include an insulating material. For example, the interlayer insulating layer 113 may include an inorganic insulating material, such as silicon oxide (SiO) or silicon nitride (SiN). The interlayer insulating layer 113 may be located on the gate insulating layer 112, but is not limited thereto.

The lower protection layer 114 may be located on the interlayer insulating layer 113. The lower protection layer 114 may suppress the damage of the driving part due to the external moisture and shocks. The lower protection layer 114 may extend along surfaces of the first transistor T1 and the second transistor T2. The lower protection layer 114 may be in contact with the interlayer insulating layer 113 at the outside of the driving part located in each sub pixel RSP, GSP, BSP.

The lower protection layer 114 may include an insulating material. For example, the lower protection layer 114 may include an inorganic insulating material, such as silicon oxide (SiO) or silicon nitride (SiN), but is not limited thereto.

The overcoat layer 115 may be located on the lower protection layer 114. The overcoat layer 115 may remove a step caused by the driving part of each sub pixel RSP, GSP, BSP. For example, a top surface of the overcoat layer 115 which is opposite to the substrate 110 may be a flat surface.

The overcoat layer 115 may include an insulating material. The overcoat layer 115 may include a material different from that of the lower protection layer 114. For example, the overcoat layer 115 may include an organic insulating material, but is not limited thereto.

The first transistor T1 may include a first semiconductor layer 121, a first gate electrode 122, a first source electrode 123, and a first drain electrode 124.

For example, the first semiconductor layer 121 may be located between the buffer layer 111 and the gate insulating layer 112 and the first gate electrode 122 may be located between the gate insulating layer 112 and the interlayer insulating layer 113. The first source electrode 123 and the first drain electrode 124 may be located between the interlayer insulating layer 113 and the lower protection layer 114. The first gate electrode 122 may overlap a channel region of the first semiconductor layer 121. The first source electrode 123 may be electrically connected to the source region of the first semiconductor layer 121. The first drain electrode 124 may be electrically connected to the drain region of the first semiconductor layer 121.

The second transistor T2 may include a second semiconductor layer 131, a second gate electrode 132, a second source electrode 133, and a second drain electrode 134.

For example, the second semiconductor layer 131 may be located on the same layer as the first semiconductor layer 121 and the second gate electrode 132 may be located on the same layer as the first gate electrode 122. The second source electrode 133 and the second drain electrode 134 may be located on the same layer as the first source electrode 123 and the first drain electrode 124.

The first transistor T1 may be formed simultaneously with the second transistor T2.

The first light emitting diode 140 and the second light emitting diode 150 of each sub pixel RSP, GSP, BSP may be located on the overcoat layer 115 of each sub pixel RSP, GSP, BSP. For example, a first lower electrode 141 of the first light emitting diode 140 may be electrically connected to the first drain electrode 124 (or the first source electrode 123) of the first transistor T1 through a contact hole which passes through the lower protection layer 114 and the overcoat layer 115. A second lower electrode 151 of the second light emitting diode 150 may be electrically connected to the second drain electrode 134 (or the second source electrode 133) of the second transistor T2 through a contact hole which passes through the lower protection layer 114 and the overcoat layer 115.

The first light emitting diode 140 may emit light representing a specific color. For example, the first light emitting diode 140 may include the first lower electrode 141, a first emission layer 142, and a first upper electrode 143 which are sequentially laminated on the substrate 110. At this time, the first lower electrode 141 may be an anode electrode of the first light emitting diode 140 and the first upper electrode 143 may be a cathode electrode of the first light emitting diode 140.

The first lower electrode 141 may include a conductive material. The first lower electrode 141 may include a material having a high reflectance. For example, the first lower electrode 141 may include metal, such as aluminum (Al), or silver (Ag). The first lower electrode 141 may have a multi-layered structure. For example, the first lower electrode 141 may have a structure in which a reflective electrode formed of a metal is located between transparent electrodes formed of a transparent conductive material, such as ITO and IZO.

The first emission layer 142 may generate light with luminance corresponding to a voltage difference between the first lower electrode 141 and the first upper electrode 143. For example, the first emission layer 142 may include an emission material layer (EML) including an emission material. The emission material may include an organic material, an inorganic material, or a hybrid material.

The first emission layer 142 may have a multi-layered structure. For example, the first emission layer 142 may further include at least one of a hole injection layer HIL, a hole transport layer HTL, an electron transport layer ETL, and an electron injection layer EIL.

The first upper electrode 143 may include a conductive material. The first upper electrode 143 may include a different material from that of the first lower electrode 141. A transmittance of the first upper electrode 143 may be higher than a transmittance of the first lower electrode 141. For example, the first upper electrode 143 may be a transparent electrode formed of a transparent conductive material, such as ITO and IZO. Alternatively, the first upper electrode 143 may be a transparent electrode in which the metal material is formed with a very thin thickness. Accordingly, in the display device 100 according to the exemplary embodiment of the present disclosure, light generated by the first emission layer 142 may be emitted through the first upper electrode 143.

The second light emitting diode 150 may implement the same color as the first light emitting diode 140 disposed in the same sub pixel RSP, GSP, BSP. The second light emitting diode 150 may have the same configuration as the first light emitting diode 140. For example, the second light emitting diode 150 may include a second lower electrode 151, a second emission layer 152, and a second upper electrode 153 which are sequentially laminated on the substrate 110. At this time, the second lower electrode 151 may be an anode electrode of the second light emitting diode 150 and the second upper electrode 153 may be a cathode electrode of the second light emitting diode 150.

The second lower electrode 151 may correspond to the first lower electrode 141, the second emission layer 152 may correspond to the first emission layer 142, and the second upper electrode 153 may correspond to the first upper electrode 143. For example, the second lower electrode 151 may be formed for the second light emitting diode 150 with the same structure as the first lower electrode 141 and this is the same for the second emission layer 152 and the second upper electrode 153. For example, the first light emitting diode 140 and the second light emitting diode 150 may be formed to have the same structure. However, it is not limited thereto and in some cases, at least a partial configuration of the first light emitting diode 140 and the second light emitting diode 150 may be formed to be different.

In the exemplary embodiment, the second emission layer 152 may be spaced apart from the first emission layer 142. Therefore, in the display device according to the exemplary embodiment of the present disclosure, light emission by a leakage current may be suppressed.

According to the exemplary embodiment of the present disclosure, in the display device 100, light may be generated by only one of the first emission layer 142 and the second emission layer 152 by the selection of the user or according to a predetermined condition.

The second lower electrode 151 of each sub pixel RSP, GSP, BSP may be spaced apart from the first lower electrode 141 of the corresponding sub pixel RSP, GSP, BSP. For example, a bank insulating layer 116 may be located between the first lower electrode 141 and the second lower electrode 151 of each sub pixel RSP, GSP, BSP. The bank insulating layer 116 may include an insulating material. For example, the bank insulating layer 116 may include an organic insulating material. The bank insulating layer 116 may include a material different from that of the overcoat layer 115, but is not limited thereto.

The second lower electrode 151 of each sub pixel RSP, GSP, BSP may be insulated from the first lower electrode 141 of the corresponding sub pixel RSP, GSP, BSP by the bank insulating layer 116. For example, the bank insulating layer 160 may cover an edge of the first lower electrode 141 and an edge of the second lower electrode 151 located in each sub pixel RSP, GSP, BSP.

The bank insulating layer 160 may divide an emission area EA1 of the first light emitting diode 140 and an emission area EA2 of the second light emitting diode 150. For example, the emission area EA1 of the first light emitting diode 140 may be divided by an edge area of the first lower electrode 141 covered by the bank insulating layer 160. The emission area EA2 of the second light emitting diode 150 may be divided by an edge area of the second lower electrode 151 covered by the bank insulating layer 160. At this time, referring to FIG. 4, a size of the emission area EA1 of the first light emitting diode 140 divided in each sub pixel RSP, GSP, BSP may be larger than the emission area EA2 of the second light emitting diode 150, but is not limited thereto.

The first emission layer 142 and the first upper electrode 143 of the first light emitting diode 140 located in each sub pixel RSP, GSP, BSP may be disposed on the first lower electrode 141 and the bank insulating layer 116. Specifically, the first emission layer 142 and the first upper electrode 143 may be laminated on a partial area of the first lower electrode 141 exposed by the bank insulating layer 116 and the bank insulating layer 116. The second emission layer 152 and the second upper electrode 153 of the second light emitting diode 150 located in each sub pixel RSP, GSP, BSP may be disposed on the second lower electrode 151 and the bank insulating layer 116. Specifically, the second emission layer 152 and the second upper electrode 153 may be laminated on a partial area of the second lower electrode 151 exposed by the bank insulating layer 116 and the bank insulating layer 116.

The second upper electrode 153 of each sub pixel RSP, GSP, BSP may be electrically connected to the first upper electrode 143 of the corresponding sub pixel RSP, GSP, BSP. For example, a voltage applied to the second upper electrode 153 of the second light emitting diode 150 located in each sub pixel RSP, GSP, BSP may be equal to a voltage applied to the first upper electrode 143 of the first light emitting diode 140 located in the corresponding sub pixel RSP, GSP, BSP. The second upper electrode 153 of each sub pixel RSP, GSP, BSP may include the same material as the first upper electrode 143 of the corresponding sub pixel RSP, GSP, BSP. For example, the second upper electrode 153 of each sub pixel RSP, GSP, BSP may be formed simultaneously with the first upper electrode 143 of the corresponding sub pixel RSP, GSP, BSP. The second upper electrode 153 of each sub pixel RSP, GSP, BSP extends to a top surface of the bank insulating layer 116 to be in direct contact with the first upper electrode 143 of the corresponding sub pixel RSP, GSP, BSP. Luminance of the first lens areas BNE, RNE, and GNE and luminance of the second lens areas BWE, RWE, and GWE located in each sub pixel RSP, GSP, BSP may be controlled by a driving current generated in the corresponding sub pixel RSP, GSP, BSP.

The encapsulation member 180 may be located on the first light emitting diode 140 and the second light emitting diode 150 of each sub pixel RSP, GSP, BSP. The encapsulation member 180 may suppress the damage of the light emitting diodes 140 and 150 due to moisture and shocks from the outside. The encapsulation member 180 may have a multi-layered structure. For example, the encapsulation member 180 may include a first encapsulation layer 181, a second encapsulation layer 182, and a third encapsulation layer 183 which are sequentially laminated, but the exemplary embodiments of the present disclosure are not limited thereto. The first encapsulation layer 181, the second encapsulation layer 182, and the third encapsulation layer 183 may include an insulating material. The second encapsulation layer 182 may include a material different from those of the first encapsulation layer 181 and the third encapsulation layer 183. For example, the first encapsulation layer 181 and the third encapsulation layer 183 are inorganic encapsulation layers including an inorganic insulating material and the second encapsulation layer 182 may include an organic encapsulation layer including an organic insulating material. Therefore, the light emitting diodes 140 and 150 of the display device 100 may efficiently suppress the damage due to the moisture and shocks from the outside.

The touch sensor unit 190 may be located on the encapsulation member 180. The touch sensor unit 190 may be disposed above the first light emitting diode 140 and the second light emitting diode 150 in the active area. The touch sensor unit 190 may be configured to sense external touch input of the display device using a user's finger, a touch pen, or the like.

Referring to FIGS. 5 and 6, in the touch sensor unit 190 of each sub pixel RSP, GSP, BSP, a plurality of first openings OP1 are disposed so as to overlap the emission area EA1 of the first light emitting diode 140 and a second opening OP2 is disposed so as to overlap the emission area EA2 of the second light emitting diode 150. At this time, side surfaces of the plurality of first openings OP1 and the second opening OP2 may be inclined surfaces. In one embodiment, the first openings OP1 and the second openings OP2 widen in a direction away from the substrate 110.

The touch sensor unit 190 includes a plurality of bridge electrodes 191, a plurality of touch electrodes 192, and a touch insulating layer 117 between the bridge electrodes 191 and the touch electrodes 192.

The plurality of bridge electrodes 191 may be located on the encapsulation member 180. The plurality of bridge electrodes 191 may be located on the encapsulation member 180 to be spaced apart from each other. The spaced areas of the plurality of bridge electrodes 191 may overlap the emission area EA1 of the first light emitting diode 140 and the emission area EA2 of the second light emitting diode 150. At this time, the spaced area of the plurality of bridge electrodes 191 may correspond to the plurality of first opening OP1 and the second opening OP2.

For example, the plurality of bridge electrodes 191 may include a metal material, such as titanium (Ti), aluminum (Al), silver (Ag), copper (Cu), and a magnesium-silver alloy (Mg:Ag), or may be formed of a material having a light reflection characteristic, but is not limited thereto.

The touch insulating layer 117 may be located on the plurality of bridge electrodes 191. The touch insulating layer 117 is disposed between the plurality of bridge electrodes 191 and the plurality of touch electrodes 192 to insulate the plurality of bridge electrodes 191 and the plurality of touch electrodes 192 in an area in which the touch insulating layer 117 is disposed. For example, the touch insulating layer 117 may be configured by an organic insulating material, but is not limited thereto.

Referring to FIGS. 5 and 6, the touch insulating layer 117 is disposed so as to enclose (e.g., surround) side surfaces of the plurality of first openings OP1 and the second opening OP2. That is, in the touch sensor unit 190, the touch insulating layer 117 may not be disposed in the plurality of first openings OP1 and the second opening OP2.

The plurality of touch electrodes 192 may be located on the touch insulating layer 117. The plurality of touch electrodes 192 may be disposed on side surfaces of the plurality of first openings OP1 and the second opening OP2 in the touch sensor unit 190. Thus, a portion of each of the plurality of touch electrodes 192 is disposed within a corresponding first opening OP1 from the plurality of first openings OP1 or is disposed within a corresponding second opening OP2. As shown in FIGS. 5 and 6, the portion of the touch electrode 192 disposed in either the first opening OP1 or the second opening OP2 is slanted (e.g., a slanted portion) with respect to the bridge electrode 191.

The plurality of touch electrodes 192 may be electrically connected to the plurality of bridge electrodes 191. For example, the plurality of touch electrodes 192 extends to side surfaces of the plurality of first openings OP1 and the second opening OP2 to be electrically connected to the plurality of bridge electrodes 191.

The plurality of touch electrodes 192 may be disposed on the touch insulating layer 117 to be spaced apart from each other. The spaced areas of the plurality of touch electrodes 192 may overlap the emission area EA1 of the first light emitting diode 140 and the emission area EA2 of the second light emitting diode 150. At this time, the spaced area of the plurality of touch electrodes 192 may correspond to the plurality of first opening OP1 and the second opening OP2.

The plurality of touch electrodes 192 may be formed of a material having a light reflection characteristic. For example, the plurality of touch electrodes 192 may include a metal material, such as titanium (Ti), aluminum (Al), silver (Ag), copper (Cu), and a magnesium-silver alloy (Mg:Ag), but is not limited thereto.

In the meantime, a touch buffer layer may be further disposed between the encapsulation member 180 and the bridge electrode 191 of the touch sensor unit 190, but is not limited thereto.

The plurality of first lenses 161 and the second lens 162 may be located on the encapsulation member 180 and the touch sensor unit 190 of each sub pixel RSP, GSP, BSP. The plurality of first lenses 161 may be disposed so as to correspond to the plurality of first openings OP1 and the second lens 162 may be disposed so as to correspond to the second opening OP2. The plurality of first lenses 161 may be disposed in the plurality of first openings OP1 and protrude above the first openings and the second lens 162 may be disposed in the second opening OP2 and protrude above the second opening. Therefore, the plurality of first lenses 161 and the second lens 162 may be disposed so as to be in contact with the touch electrode 192 in the plurality of first openings OP1 and the second opening OP2.

The plurality of first lenses 161 may be located on the first lens areas RNE, GNE, and BNE of the sub pixels RSP, GSP, and BSP.

For example, light generated by the first light emitting diode 140 in the sub pixels RSP, GSP, and BSP may be emitted through the plurality of first lenses 161 of the corresponding sub pixels RSP, GSP, and BSP. At this time, a traveling direction of light which passes through the plurality of first lenses 161 may be limited to the first direction and/or the second direction.

A planar shape of the plurality of first lenses 161 located in the sub pixels RSP, GSP, and BSP may be a rectangular shape. In this case, the traveling direction of light emitted from the first lenses areas RNE, GNE, and BNE of the sub pixels RSP, GSP, and BSP may be limited to the first direction and the second direction. However, the planar shape of the plurality of first lenses 161 may be a circular shape, but is not limited thereto.

The contents supplied by the first lens areas RNE, GNE, and BNE of the sub pixels RSP, GSP, and BSP may not be shared by the people around the user. When the contents are provided through the first lens areas RNE, GNE, and BNE, the contents are provided at the first viewing angle range which is narrower than the second viewing angle range supplied by the second lens areas RWE, GWE, and BWE and this may be referred to as a first mode.

The second lens 162 may be located on the second lens areas BWE, RWE, and GWE of the sub pixels RSP, GSP, and BSP.

For example, light generated by the second light emitting diode 150 of each sub pixel RSP, GSP, BSP may be emitted through the second lens 162 of the corresponding sub pixel RSP, GSP, BSP.

The second lens 162 may have a shape that does not limit light of at least one direction. For example, a planar shape of the second lens 162 in each sub pixel RSP, GSP, BSP may have a bar shape which extends in the first direction.

In this case, a traveling direction of light emitted from the second lens areas BWE, RWE, and GWE of each sub pixel RSP, GSP, BSP may not be limited in the first direction. For example, contents (or images) provided through the second lens areas BWE, RWE, and GWE of each sub pixel RSP, GSP, BSP may be shared by surrounding people which is adjacent to the user in the first direction. When the contents are provided through the second lens areas BWE, RWE, and GWE, the contents are provided at the second viewing angle range which is wider than the first viewing angle range supplied by the first lens areas BNE, RNE, and GNE and this may be referred to as a second mode.

Areas of the sub pixel RSP, GSP, BSP in which the plurality of first lenses 161 is disposed may be referred to as a plurality of first emission areas RE1, GE1, and BE1. For example, the plurality of first emission areas RE1, GE1, and BE1 may be areas in which the light generated by the first light emitting diode 140 is emitted through the first lens 161.

Areas of the sub pixel RSP, GSP, BSP in which the second lens 162 is disposed may be referred to as second lens areas RWE, GWE, and BWE. For example, the second lens areas RWE, GWE, and BWE may be areas in which the light generated by the second light emitting diode 150 is emitted through the second lens 162.

The plurality of first emission areas RE1, GE1, and BE1 included in the first lens areas RNE, GNE, and BNE of the sub pixels RSP, GSP, and BSP may have a shape corresponding to the plurality of first lenses 161 located on the first lens areas RNE, GNE, and BNE of the corresponding sub pixels RSP, GSP, and BSP. For example, a planar shape of the plurality of first emission areas RE1, GE1, and BE1 defined in the first lens areas RNE, GNE, and BNE of the sub pixels RSP, GSP, and BSP may be a rectangular shape.

At this time, referring to FIG. 4, the plurality of first lenses 161 may be arranged in a matrix in the emission area EA1 of the first light emitting diode 140. Therefore, the bridge electrode 191 and the touch electrode 192 may be disposed between the plurality of first lenses 161 on the plane.

The plurality of first lenses 161 located on the first lens areas RNE, GNE, and BNE of the sub pixels RSP, GSP, and BSP may have the same shape as the plurality of first emission areas RE1, GE1, and BE1 included in the first lens areas RNE, GNE, and BNE of the corresponding sub pixels RSP, GSP, and BSP. Further, the plurality of first lenses 161 may have a size larger than the plurality of first emission areas RE1, GE1, and BE1 so that efficiency of light emitted from the first emission areas RE1, GE1, and BE1 of the sub pixels RSP, GSP, and BSP may be improved.

The second emission areas RE2, GE2, and BE2 included in the second lens areas RWE, GWE, and BWE of the sub pixels RSP, GSP, and BSP may have a shape corresponding to the second lens 162 located on the second lens areas RWE, GWE, and BWE of the corresponding sub pixels RSP, GSP, and BSP. For example, the planar shape of the second emission areas RE2, GE2, and BE2 included in the second lens areas RWE, GWE, and BWE of the sub pixels RSP, GSP, and BSP have a bar shape extending in the first direction.

The second lens 162 located on the second lens areas RWE, GWE, and BWE of the sub pixels RSP, GSP, and BSP may have the same size as the second emission areas RE2, GE2, and BE2 included in the second lens areas RWE, GWE, and BWE of the corresponding sub pixels RSP, GSP, and BSP. Further, the second lens 162 may have a size larger than the second emission areas RE2, GE2, and BE2 so that efficiency of light emitted from the second emission areas RE2, GE2, and BE2 of the sub pixels RSP, GSP, and BSP may be improved.

In the exemplary embodiment, the first lens areas RNE, GNE, and BNE of the sub pixels RSP, GSP, and BSP may include the plurality of first emission areas RE1, GE1, and BE1. The second lens areas RWE, GWE, and BWE of the sub pixels RSP, GSP, and BSP may include one second emission area RE2, GE2, BE2, respectively.

In the exemplary embodiment, the plurality of first lenses 161 may be disposed on the first lens areas RNE, GNE, and BNE of the sub pixels RSP, GSP, and BSP. One second lens 162 may be disposed on the second lens areas RWE, GWE, and BWE of the sub pixels RSP, GSP, and BSP. In the exemplary embodiment, an area of each of the first emission areas RE1, GE1, and BE1 located in the first lens areas RNE, GNE, and BNE of the plurality of sub pixels RSP, GSP, and BSP may be specified by a specific value. For example, the size of each of the first emission areas RE1, GE1, and BE1 located in the first lens areas RNE, GNE, and BNE may be implemented to be the same. The first emission areas RE1, GE1, and BE1 included in the first lens areas RNE, GNE, and BNE of the plurality of sub pixels RSP, GSP, and BSP may have the same area as the first emission areas RE1, GE1, and BE1 included in the first lens areas RNE, GNE, and BNE of the adjacent sub pixels RSP, GSP, and BSP.

In the exemplary embodiment, the number of the plurality of first emission areas RE1, GE1, BE1 may vary in each sub pixel RSP, GSP, BSP. For example, the number of first emission areas BE1 defined in the first lens area BNE of the blue sub pixel BSP may be larger than the number of first emission areas GE1 defined in the first lens area GNE of the green sub pixel GSP. The number of first emission areas GE1 defined in the first lens area GNE of the green sub pixel GSP may be larger than the number of first emission areas RE1 defined in the first lens area RNE of the red sub pixel RSP. In this case, the efficiency deviation of the first light emitting diodes 140 located on the first lens areas RNE, GNE, and BNE of the sub pixels RSP, GSP, and BSP may be compensated by the number of first emission areas RE1, GE1, and BE1 defined in the first lens areas RNE, GNE, and BNE of each sub pixel RSP, GSP, and BSP.

In the exemplary embodiment, the second emission areas RE2, GE2, and BE2 may have different sizes in each sub pixel RSP, GSP, BSP. For example, the second emission area BE2 of the blue sub pixel BSP may have a different size from the second emission area GE2 of the green sub pixel GSP and have a different size from the second emission area RE2 of the red sub pixel RSP. A size of the second emission area BE2 of the blue sub pixel BSP may be larger than the size of the second emission area GE2 of the green sub pixel GSP. A size of the second emission area GE2 of the green sub pixel GSP may be larger than the size of the second emission area RE2 of the red sub pixel RSP. Accordingly, in the display device according to the exemplary embodiment of the present disclosure, the efficiency deviation of the second light emitting diode 150 located on the second lens areas RWE, GWE, and BWE of the sub pixels RSP, GSP, and BSP may be compensated by the size of the second emission areas RE2, GE2, and BE2 defined in the second lens areas RWE, GWE, and BWE of each sub pixel RSP, GSP, BSP.

In the exemplary embodiment, a lens protection layer 170 may be located on the plurality of first lenses 161 and the second lens 162 of the sub pixels RSP, GSP, and BSP. The lens protection layer 170 may include an insulating material. For example, the lens protection layer 170 may include an organic insulating material. A refractive index of the lens protection layer 170 may be smaller than a refractive index of the first lens 161 and a refractive index of the second lens 162 located in each sub pixel RSP, GSP, BSP. Accordingly, in the display device 100 according to the exemplary embodiment of the present disclosure, light which passes through the first lens 161 and the second lens 162 in each sub pixel RSP, GSP, BSP may not be reflected toward the substrate 110 by the refractive index difference from the lens protection layer 170.

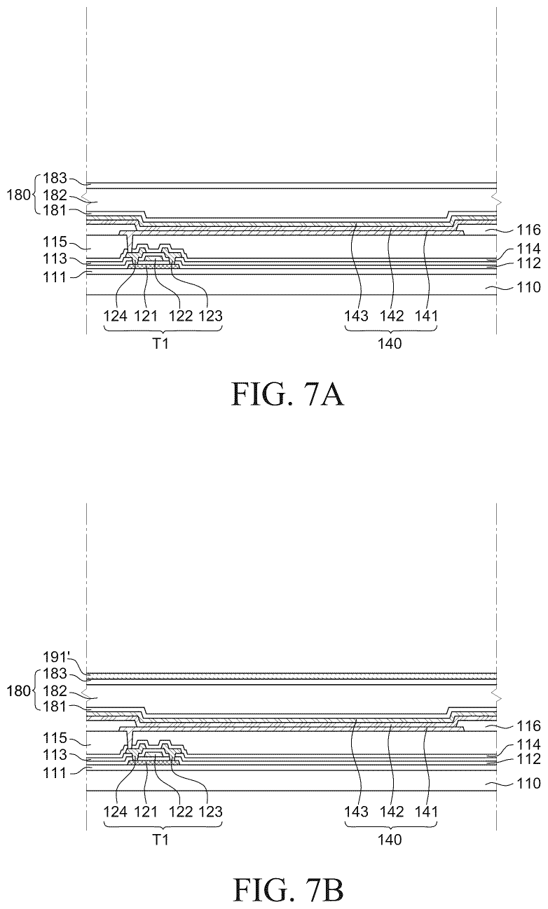

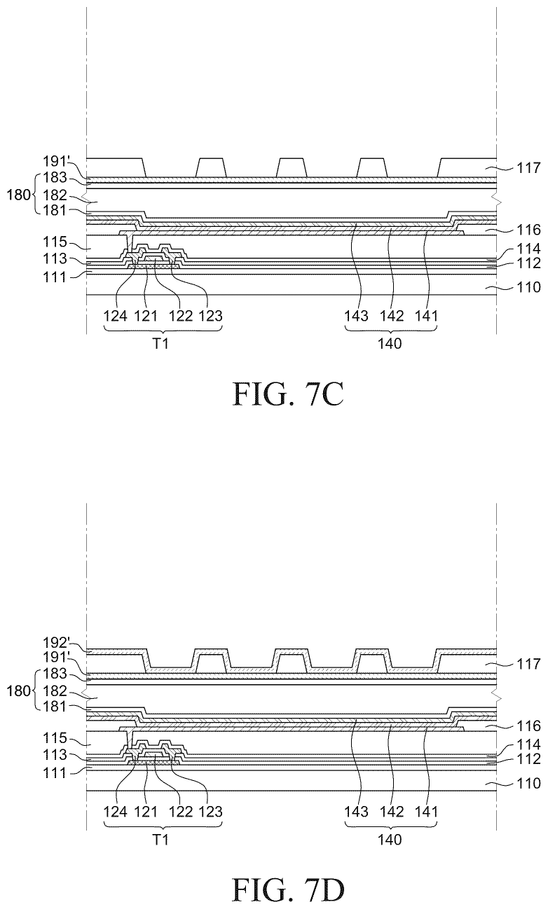

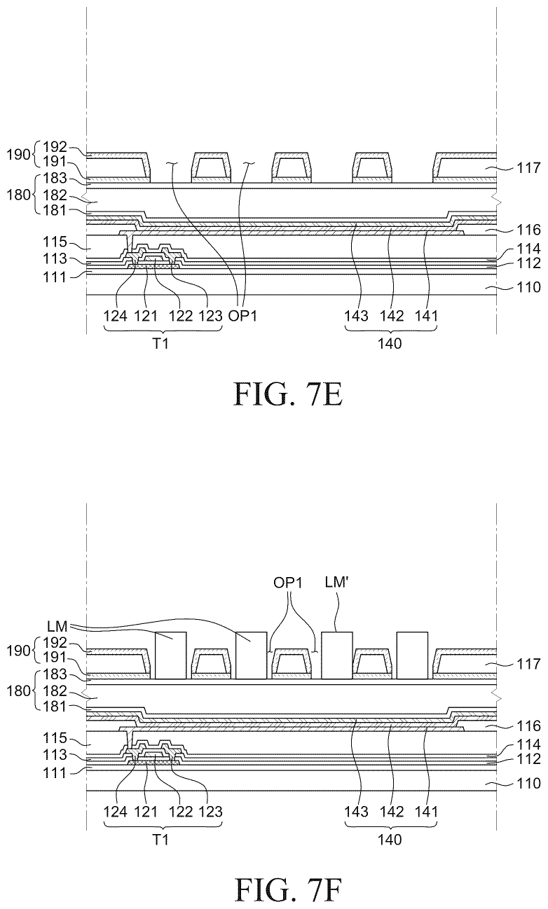

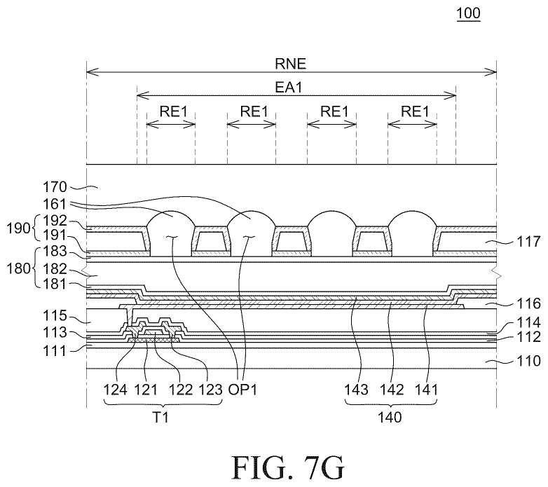

Hereinafter, a manufacturing process of a display device according to an exemplary embodiment of the present disclosure will be described in detail with reference to FIGS. 7A to 7G.

FIGS. 7A to 7G are process diagrams for explaining a manufacturing process of a display device according to an exemplary embodiment of the present disclosure. However, in FIGS. 7A to 7G, for the convenience of description, only an area corresponding to a first lens area RNE of a red sub pixel RSP, among first lens areas RNE, GNE, and BNE and second lens areas RWE, GWE, and BWE of the plurality of sub pixels RSP, GSP, and BSP, is illustrated. However, the other sub pixels may also be formed by the same process.

First, referring to FIG. 7A, a first transistor T1 is formed on the substrate 110 so as to correspond to each sub pixel RSP, GSP, BSP and a first light emitting diode 140 which is electrically connected to the first transistor T1 is formed above the first transistor T1. The encapsulation member 180 is formed above the first light emitting diode 140 so as to cover the first light emitting diode 140. At this time, the encapsulation member 180 may have a multi-layered structure including a first encapsulation layer 181, a second encapsulation layer 182, and a third encapsulation layer 183 which are sequentially laminated.

Next, referring to FIG. 7B, a material 191′ for forming a bridge electrode of the touch sensor unit 190 is disposed on the encapsulation member 180. At this time, the material 191′ for forming a bridge electrode may be disposed on the entire surface of the encapsulation member 180 and is patterned by a subsequent process to form a bridge electrode 191.

Next, referring to FIG. 7C, a touch insulating layer 117 is formed on the material 191′ for forming a bridge electrode. The touch insulating layer 117 may be disposed so as to expose the material 191′ for forming a bridge electrode. For example, the process of placing the touch insulating layer 117 to expose the material 191′ for forming a bridge electrode may be performed during the process of patterning a material for forming the touch insulating layer 117 above the material 191′ for forming a bridge electrode, but is not limited thereto.

Next, referring to FIG. 7D, a material 192′ for forming a touch electrode is disposed on the touch insulating layer 117. At this time, the material 192′ for forming a touch electrode may be disposed on a top surface of the touch insulating layer 117 and a top surface of the material 191′ for forming a bridge electrode exposed from the touch insulating layer 117. At this time, the material 192′ for forming a touch electrode may be disposed so as to be in contact with the material 191′ for forming a bridge electrode exposed from the touch insulating layer 117.

Next, referring to FIG. 7E, a plurality of first openings OP1 are formed in a contact area of the material 192′ for forming a touch electrode and the material 191′ for forming a bridge electrode. Therefore, a plurality of bridge electrodes 191 and a plurality of touch electrodes 192 of the touch sensor unit 190 may be formed.

In the meantime, a step of forming the plurality of bridge electrodes 191 and a step of forming the plurality of touch electrodes 192 may be simultaneously completed using the same mask by the process of forming the plurality of first openings OP1. Therefore, in the display device 100 according to the exemplary embodiment of the present disclosure, as compared with an example that performs the step of forming the plurality of touch electrodes 192 after forming the step of forming the plurality of bridge electrodes 191, the number of processes for forming the plurality of bridge electrodes 191 and the plurality of touch electrodes 192 and the number of patterning masks may be reduced.

Next, referring to FIG. 7F, a lens forming material LM is disposed in each of the plurality of first openings OP1. For example, the process of placing the lens forming material LM may be configured by a process of patterning the lens forming material LM on the encapsulation member 180 exposed from the touch sensor unit 190 by the plurality of first openings OP1, but is not limited thereto.

Next, referring to FIG. 7G, the lens forming material LM disposed in the plurality of first openings OP1 of the touch sensor unit 190 may be formed as a first lens 161 by a thermal reflow process. For example, during the process of forming the first lens 161, the lens forming material LM is melted by the thermal reflow process. The lens forming melted material LM becomes a liquid state and the first opening is filled with the liquid lens forming material. Further, the liquid lens forming material which is not accommodated in the first opening is disposed to protrude above the first opening and a top surface of the lens forming material of the liquid state may have a round, for example, a spherical convex lens shape by a surface tension. Thereafter, when the liquid lens forming material is cured, the first lens 161 may be formed. Therefore, the first lens 161 may be formed as a convex lens with a convex top surface.

Next, a process for forming the lens protection layer 170 may be formed on the plurality of first lenses 161 and the touch sensor unit 190.

In the display device 100 according to the exemplary embodiment of the present disclosure, a process of placing the plurality of first lenses 161 in the plurality of first openings OP1 of the touch sensor unit 190 may be performed by a self-alignment method using a thermal reflow process. Therefore, the process error of the plurality of first lenses 161 during the process of placing the plurality of first lenses 161 in the plurality of first openings OP1 may be minimized.

For example, during the process of placing the lens forming material LM in each of the plurality of first openings OP1, there may be a misaligned lens forming material LM′ due to the process error, as illustrated in FIG. 7F. At this time, the misaligned lens forming material LM′ is melted by the thermal reflow process and the misaligned lens forming material in a melted liquid state is filled in the first opening OP1 and is cured to form the first lens 161. The first lens 161 formed from the misaligned lens forming material LM′ may be formed by the self-alignment method that the melted material is cured along the surface of the first opening OP1. Therefore, even though there is a misaligned lens forming material LM′, the first lens 161 may be formed to be the substantially same as the lens forming material LM which is normally aligned so that the process error of the first lens 161 in the first opening OP1 may be minimized. Therefore, in the display device 100 according to the exemplary embodiment of the present disclosure, the process error of the plurality of first lenses 161 during the process of placing the plurality of first lenses 161 in the plurality of first openings OP1 may be minimized.

Hereinafter, an effective area and a vertical luminance of the plurality of first lenses 161 of a display device 100 according to a comparative embodiment and the exemplary embodiment of the present disclosure will be described in detail with reference to Table 1 together.

TABLE 1

| | Comparative | Exemplary embodiment of |
|---|---|---|
| Items to be checked | embodiment | present disclosure |
| Area of lens compared to | 62% | 62% |
| emission area | | |
| Effective area compared to | 13.9% | 15.4% |
| emission area | | |
| Vertical luminance | 100% | 243% |
| A+ Min Luminance | 100% | 419% |

At this time, evaluation was performed with the following conditions: in the display device according to the comparative embodiment, two first lenses were disposed on the emission area with a limited area. In the display device 100 according to the exemplary embodiment of the present disclosure, on the emission area with the same area as the display device according to the comparative embodiment, 12 first lenses 161 which were smaller than the first lens of in the display device according to the comparative embodiment (for example, the first lens 161 disposed in the red sub pixel RSP of FIG. 4) were disposed. Here, the effective area refers to an effective area contributing to actual emission, the vertical luminance is a luminance in the front 0°, and A+ Min luminance is a luminance in a viewing area within ±10° left and right, +8° and −4° up and down from the front 0° according to one embodiment.

Referring to [Table 1], the area of the plurality of first lenses of the display device according to the comparative embodiment is 62% of the area of the emission area and the area of the plurality of first lenses 161 of the display device 100 according to the exemplary embodiment of the present disclosure is 62% of the area of the emission area. That is, in the display device according to the comparative embodiment and the display device 100 according to the exemplary embodiment of the present disclosure, even though the plurality of first lenses with different sizes are disposed in the same area, a total area of the lenses in one sub pixel is set to be the same.

As this time, the effective area of the plurality of first lenses of the display device according to the comparative embodiment is 13.9% of the emission area and the effective area of the plurality of first lenses 161 of the display device 100 according to the exemplary embodiment of the present disclosure is 15.4% of the emission area. Therefore, it is understood that the effective area in the display device 100 according to the exemplary embodiment of the present disclosure in which the plurality of first lenses 161 with the smaller area is disposed in the same area is improved. This is because in the display device 100 according to the exemplary embodiment of the present disclosure, the interference between the plurality of first lenses 161 disappears so that the distance between lenses may be reduced.

Referring to Table 1, when a vertical luminance of the plurality of first lenses of the display device according to the comparative embodiment was assumed as 100%, a vertical luminance of the plurality of first lenses 161 of the display device 100 according to the exemplary embodiment of the present disclosure was improved to 243%. Further, when an A+ Min luminance of the plurality of first lenses of the display device according to the comparative embodiment was assumed as 100%, an A+ Min luminance of the plurality of first lenses 161 of the display device 100 according to the exemplary embodiment of the present disclosure was improved to 419%. Therefore, it is understood that in the display device 100 according to the exemplary embodiment of the present disclosure in which the plurality of first lenses 161 having a smaller size is disposed on the same area, the vertical luminance and the A+ Min luminance are also significantly improved.

In the display device, a first lens and a second lens which provide different viewing angle modes may be disposed above the light emitting diode and the touch sensor unit in one pixel to selectively implement a viewing angle mode. At this time, when a plurality of lenses are misaligned due to the process error during the process of placing a plurality of lenses above the light emitting diode and the touch sensor unit, the optical characteristics such as the efficiency and the vertical luminance of light emitted from the emission area of the light emitting diode may deteriorate. In the meantime, such a misalignment problem may also be generated during the process of placing a touch sensor unit above the light emitting diode and there is a problem in that the emission area is reduced by the misaligned touch sensor unit. That is, the more the configuration to be disposed above the light emitting diode, the more severe the misalignment problems described above. Therefore, when the misalignment occurs, misaligned components overlap to reduce the effective area of the plurality of lenses so that there may also be an additional problem in that the performance for selectively implementing the viewing angle mode deteriorates.

At this time, the smaller the size of the lens in the same process condition, the higher the probability of the process error may occur. The smaller the distance between the plurality of lenses, the higher the probability of interference between lenses due to the process error of each lens. Therefore, it may be difficult to design the size of the plurality of lenses to be disposed in the limited area and the distance between the lenses to be reduced so that a degree of freedom of design for the size of the plurality of lenses and the distance between the lenses may be limited.

In the meantime, the larger the size of the plurality of lenses, the smaller the area in which the plurality of lenses is disposed in the same area, that is, the effective area. Therefore, when the distance between the lenses is reduced to dispose more lenses in the same area, the interference area between the plurality of lenses due to the misalignment of each of the plurality of lenses is increased to reduce the effective area and reduce the luminous efficiency of the display device. Therefore, a technique of placing a plurality of lenses with a reduced size in a limited area to reduce the placement distance between lenses may be requested.

In the display device 100 according to the exemplary embodiment of the present disclosure, the plurality of first lenses 161 are disposed to minimize or at least reduce the process error so that the effective area of the first lens 161 which is disposed in the limited area may be further increased. Accordingly, the luminous efficiency and the vertical luminance of the display device 100 may be improved. Specifically, in the display device 100 according to the exemplary embodiment of the present disclosure, the plurality of first lenses 161 are disposed in the plurality of first openings OP1 of the touch sensor unit 190 to be self-aligned using the thermal reflow process. Therefore, the process error during the process of placing the bridge electrode 191, the touch electrode 192, and the plurality of first lenses 161 disposed above the first light emitting diode 140 may be minimized or at least reduced. Accordingly, the process error may be minimized or at least reduced so that the degree of freedom of design for the plurality of first lenses 161 is improved to dispose the plurality of first lenses 161 with a further reduced size. Further, the interference between the plurality of first lenses 161 is reduced to further reduce the distance between the plurality of first lenses 161. Accordingly, the plurality of first lenses 161 may be disposed in more areas on the same area and the effective area of the plurality of first lenses 161 may be increased. The interference between the plurality of first lenses 161 is minimized or reduced to increase the effective area so that the luminous efficiency to extract light from the plurality of first lenses 161 may also be improved. As seen from Table 1 above, the vertical luminance may be improved by placing the plurality of first lenses with a smaller size on the same area. Therefore, in the display device 100 according to the exemplary embodiment of the present disclosure, the plurality of first lenses may be disposed with further reduced size and the placement distance between the lenses may be reduced. Accordingly, the vertical luminance of the display device may be further improved and the performance for selectively implementing the viewing angle mode may also be improved.

Accordingly, in the display device 100 according to the exemplary embodiment of the present disclosure, the plurality of first lenses 161 are disposed to minimize or at least reduce the process error so that the effective area of the first lens 161 which is disposed in the limited area may be further increased. Further, the luminous efficiency and the vertical luminance of the display device 100 may be improved.

Further, in the display device 100 according to the exemplary embodiment of the present disclosure, side surfaces of the plurality of first openings OP1 and the second opening OP2 disposed in the touch sensor unit 190 are inclined surfaces. Therefore, the touch sensor unit 190 which is the side surfaces of the plurality of first openings OP1 and the second opening OP2 may be configured to reflect light emitted from the first light emitting diode 140 and the second light emitting diode 150 to the front direction of the display device. Therefore, the vertical luminance of light emitted from the first light emitting diode 140 and the second light emitting diode 150 below the touch sensor unit 190 may be improved.

For example, referring to FIG. 5, first light LP1 emitted from the first light emitting diode 140 is emitted at an elevated angle close to the vertical, so that the light may be emitted in the front direction of the display device through the first lens 161 without being reflected by the touch sensor unit 190.

Next, second light LP2 emitted from the first light emitting diode 140 at a lower angle than the first light LP1 may be reflected by the touch electrode 192 to be extinguished or may be reflected in a direction lower than the front direction of the display device so that the light may not be visible from the front direction of the display device.

Further, third light LP3 emitted from the first light emitting diode 140 at a lower angle than the second light LP2 is reflected by the bridge electrode 191 of the touch sensor unit 190 and the first lower electrode 141 of the first light emitting diode 140 to be emitted through another adjacent first opening OP1. At this time, the third light LP3 may be configured to have a larger angle during the process of being reflected by the bridge electrode 191 and the first lower electrode 141 and may be emitted to the front direction of the display device.

Finally, fourth light LP4 emitted from the first light emitting diode 140 at a smaller angle than the third light LP3 may be reflected by the touch electrode 192 disposed on a side surface of another adjacent first opening OP1 to be extinguished or may be reflected in a direction lower than the front direction of the display device. Therefore, the light may not be visible from the front direction of the display device.

Therefore, in the display device 100 according to the exemplary embodiment of the present disclosure, side surfaces of the plurality of first openings OP1 and the second opening OP2 disposed in the touch sensor unit 190 are disposed as inclined surfaces. Therefore, the touch sensor unit 190 which is the side surfaces of the plurality of first openings OP1 and the second opening OP2 may be configured to reflect light emitted from the first light emitting diode 140 to the front direction of the display device. Therefore, the luminance in the front direction of light emitted from the first light emitting diode 140 and the second light emitting diode 150 below the touch sensor unit 190 is increased so that the vertical luminance of the display device 100 may be further improved.

In the meantime, in the display device 100 according to the exemplary embodiment of the present disclosure, the luminous efficiency and the vertical luminance of the display device 100 are improved. Therefore, the lifespan of the display device 100 for the same power usage may be improved so that a lower power display device may be implemented.

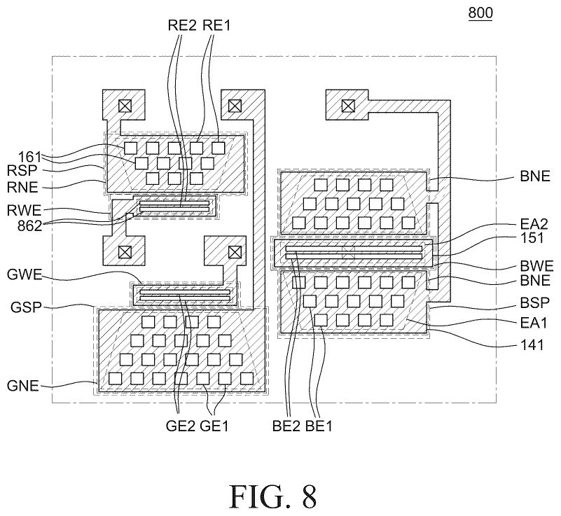

FIG. 8 is an enlarged plan view of a display device according to another exemplary embodiment of the present disclosure. The only difference between a display device 800 of FIG. 8 and the display device 100 of FIGS. 1 to 7G is that a plurality of second lenses 862 are disposed, but the other configuration is substantially the same, so that a redundant description will be omitted.

Referring to FIG. 8, a plurality of second lenses 862 may be disposed. Therefore, a plurality of second openings OP2 in which the second lenses 862 are disposed in the touch sensor unit 190 may also be disposed.

For example, the plurality of second lenses 862 may be disposed in one line in the plurality of second emission areas RE2 and the emission areas EA2 of the plurality of second light emitting diodes 150. The plurality of second lenses 862 may be disposed to extend in one direction in the plurality of second emission areas RE2 and the emission areas EA2 of the plurality of second light emitting diodes 150. Therefore, an aspect ratio of the plurality of second lenses 862 may be larger than an aspect ratio of the plurality of first lenses 161. Therefore, the plurality of second openings OP2 in which the plurality of second lenses 862 is disposed may have an aspect ratio larger than that of the plurality of first openings OP1 in which the plurality of first lenses 161 is disposed.

In the display device 800 according to another exemplary embodiment of the present disclosure, the plurality of first lenses 161 and the plurality of second lenses 862 are disposed to minimize or at least reduce the process error. Therefore, the effective areas of the plurality of first lenses 161 and the plurality of second lenses 862 disposed in a limited area may be further increased. Accordingly, the luminous efficiency and the vertical luminance of the display device 800 may be improved.

Specifically, in the display device 800 according to another exemplary embodiment of the present disclosure, the plurality of first lenses 161 and the plurality of second lenses 862 are disposed to be self-aligned in the plurality of first openings OP1 and the second opening OP2 of the touch sensor unit 190 using the thermal reflow process. Therefore, the process error during the process of placing the bridge electrode 191, the touch electrode 192, the plurality of first lenses 161, and the plurality of second lenses 862 which are disposed above the first light emitting diode 140 and the second light emitting diode 150 may be minimized. Accordingly, the process error may be minimized or at least reduced so that the degree of freedom of design for the plurality of first lenses 161 and the plurality of second lenses 862 is improved to dispose the plurality of first lenses 161 and the plurality of second lenses 862 with a reduced size. Further, the interference between the plurality of first lenses 161 and the interference between the plurality of second lenses 862 are reduced so that the distance between the plurality of first lenses 161 and the distance between the plurality of second lenses 862 may also be reduced. Therefore, the plurality of first lenses 161 and the plurality of second lenses 862 may be disposed in more areas on the same area and the effective area of the plurality of first lenses 161 and the plurality of second lenses 862 may be increased. Further, the interference between the plurality of first lenses 161 and the interference between the plurality of second lenses 862 are minimized or at least reduced to increase the effective area so that the luminous efficiency to extract light from the plurality of first lenses 161 and the plurality of second lenses 862 may also be improved. Therefore, in the display device 800 according to another exemplary embodiment of the present disclosure, the plurality of first lenses 161 and the plurality of second lenses 862 are disposed with further reduced size and the placement distance between the lenses may be reduced. Accordingly, the vertical luminance of the display device may be further improved and the performance for selectively implementing the viewing angle mode may also be improved. Accordingly, in the display device 800 according to another exemplary embodiment of the present disclosure, the plurality of first lenses 161 and the plurality of second lenses 862 are disposed to minimize the process error. Therefore, the effective areas of the plurality of first lenses 161 and the plurality of second lenses 862 disposed in a limited area may be further increased and the luminous efficiency and the vertical luminance of the display device 800 may be improved. Further, as the luminous efficiency and the vertical luminance of the display device 800 are improved, the lifespan of the display device 800 for the same power usage may be improved so that a lower power display device may be implemented.

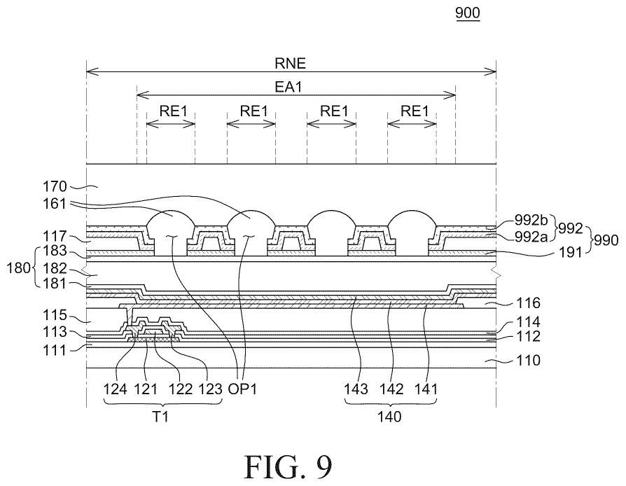

FIG. 9 is a cross-sectional view of a display device according to still another exemplary embodiment of the present disclosure. The only difference between a display device 900 of FIG. 9 and the display device 100 of FIGS. 1 to 7G is a touch electrode 992, but the other configuration is the same, so that a redundant description will be omitted.

Referring to FIG. 9, the plurality of touch electrodes 992 may include a light reflection layer 992a and a light absorption layer 992b.

The light reflection layer 992a may be disposed on the bridge electrode 191. The light reflection layer 992a may be formed of a material having a light reflection characteristic. For example, the light reflection layer 992a may include a metal material, such as titanium (Ti), aluminum (Al), silver (Ag), copper (Cu), and a magnesium-silver alloy (Mg:Ag), but is not limited thereto.

The light absorption layer 992b may be disposed on the light reflection layer 992a. The light absorption layer 992b may be formed of a material having a light absorption characteristic. For example, the light absorption layer may include niobium pentoxide (Nb₂O₅) or manganese (Mn), or may include nickel chrome (NiCr) or alumina (Al₂O₃), and may be formed of a conductive material having light absorption characteristic, but is not limited thereto.

In the meantime, the light absorption layer 992b may include a first layer, a second layer disposed on the first layer, and a third layer disposed on the second layer. For example, the light absorption layer 992b may be configured as a triple layer in which the first layer and the third layer include niobium pentoxide (Nb₂O₅) and the second layer includes nickel chrome (NiCr). Alternatively, the light absorption layer may also be configured as a triple layer in which the first layer and the third layer include manganese (Mn) and the second layer includes alumina (Al₂O₃), but is not limited thereto.

In the display device 900 according to still another exemplary embodiment of the present disclosure, the plurality of touch electrodes 992 is configured to include the light reflection layer 992a and the light absorption layer 992b so that the vertical luminance of the display device 900 may be further improved.

Specifically, in the display device 900 according to still another exemplary embodiment of the present disclosure, side surfaces of the plurality of first openings OP1 and the second opening OP2 disposed in the touch sensor unit 990 are inclined surfaces. Therefore, the touch sensor unit 990 which is the side surfaces of the plurality of first openings OP1 and the second opening OP2 may be configured to reflect light emitted from the first light emitting diode 140 and the second light emitting diode 150 to the front direction of the display device. Therefore, the vertical luminance of light emitted from the first light emitting diode 140 and the second light emitting diode 150 below the touch sensor unit 990 may be improved. At this time, the plurality of touch electrodes 992 includes the light reflection layer 992a and the light absorption layer 992b so that light emitted from the first light emitting diode 140 and the second light emitting diode 150 may be absorbed by the light absorption layer 992b which is a top surface of the touch electrode 992. Therefore, the luminance in the front direction of light emitted from the first light emitting diode 140 and the second light emitting diode 150 below the touch sensor unit 990 is increased so that the vertical luminance of the display device 900 may be further improved. Accordingly, in the display device 900 according to still another exemplary embodiment of the present disclosure, the plurality of touch electrodes 992 is configured to include the light reflection layer 992a and the light absorption layer 992b. Therefore, the vertical luminance of the display device 900 may be further improved and the lower power display device 900 with an improved lifespan may be implemented.

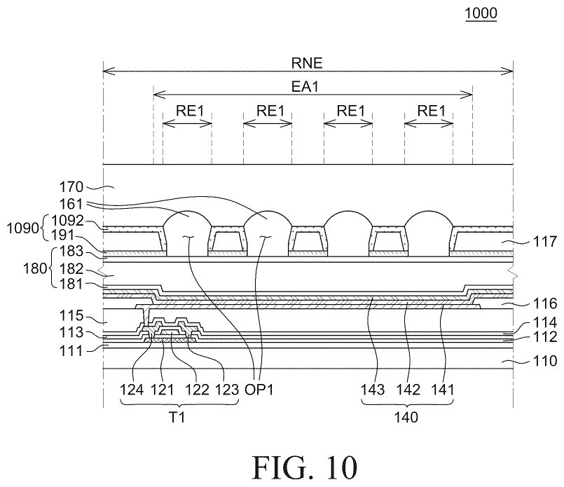

FIG. 10 is a cross-sectional view of a display device according to still another exemplary embodiment of the present disclosure. The only difference between a display device 1000 of FIG. 10 and the display device 100 of FIGS. 1 to 7G is a touch electrode 1092, but the other configuration is the same, so that a redundant description will be omitted.

The plurality of touch electrodes 1092 may be formed of a material having a light absorption characteristic. For example, the plurality of touch electrodes 1092 may include niobium pentoxide (Nb₂O₅) or manganese (Mn), or may include nickel chrome (NiCr) or alumina (Al₂O₃), and may be formed of a conductive material having light absorption characteristic, but is not limited thereto.

In the display device 1000 according to still another exemplary embodiment of the present disclosure, the plurality of touch electrodes 1092 may be formed of a material having a light absorption characteristic so that the vertical luminance of the display device 1000 may be further improved.

Specifically, in the display device 1000 according to still another exemplary embodiment of the present disclosure, side surfaces of the plurality of first openings OP1 and the second opening OP2 disposed in the touch sensor unit 1090 are inclined surfaces. Therefore, the touch sensor unit 1090 which is the side surfaces of the plurality of first openings OP1 and the second opening OP2 may be configured to reflect light emitted from the first light emitting diode 140 and the second light emitting diode 150 to the front direction of the display device. Therefore, the vertical luminance of light emitted from the first light emitting diode 140 and the second light emitting diode 150 below the touch sensor unit 1090 may be improved. At this time, the plurality of touch electrodes 1092 is formed of a material having a light absorption characteristic so that the light emitted from the first light emitting diode 140 and the second light emitting diode 150 may be absorbed by the touch electrode 1092 which is formed of a material having a light absorption characteristic. Therefore, the luminance in the front direction of light emitted from the first light emitting diode 140 and the second light emitting diode 150 below the touch sensor unit 1090 is increased so that the vertical luminance of the display device 1000 may be further improved. Accordingly, in the display device 1000 according to still another exemplary embodiment of the present disclosure, the plurality of touch electrodes 1092 is formed of a material having a light absorption characteristic. Therefore, the vertical luminance of the display device 1000 may be further improved and the lower power display device 1000 with an improved lifespan may be implemented.

The exemplary embodiments of the present disclosure can also be described as follows:

According to an aspect of the present disclosure, a display device may include a substrate in which a plurality of pixels each including a plurality of sub pixels representing different colors is disposed; a first light emitting diode and a second light emitting diode disposed in each of the plurality of sub pixels; a touch sensor unit disposed above the first light emitting diode and the second light emitting diode; a plurality of first lenses which is disposed so as to overlap an emission area of the first light emitting diode on the touch sensor unit and has a viewing angle of a first value; and a plurality of second lenses which is disposed so as to overlap an emission area of the second light emitting diode on the touch sensor unit and has a viewing angle of a second value which is higher than the first value. In the touch sensor unit, a plurality of first openings may be disposed so as to overlap the emission area of the first light emitting diode and the plurality of first lenses may be disposed so as to correspond to the plurality of first openings.

In the touch sensor unit, a second opening may be disposed so as to overlap the emission area of the second light emitting diode and the second lens may be disposed so as to correspond to the second opening.

One second opening and one second lens may be provided.

A plurality of second openings and a plurality of second lenses may be provided.

The plurality of second openings may have an aspect ratio larger than that of the plurality of first openings.

The plurality of second openings may be disposed in one line in the emission area of the second light emitting diode.

The plurality of first lenses may be disposed in a matrix in the emission area of the first light emitting diode.

The touch sensor unit may include a plurality of bridge electrodes; a touch insulating layer disposed on the plurality of bridge electrodes; and a plurality of touch electrodes which is disposed on the touch insulating layer and is electrically connected to the plurality of bridge electrodes.

The plurality of touch electrodes may be disposed on side surfaces of the plurality of first openings in the touch sensor unit.

The plurality of touch electrodes may extend to the side surfaces of the plurality of first openings on the touch insulating layer to be electrically connected to the plurality of bridge electrodes.

The first lens may be disposed so as to be in contact with the plurality of touch electrodes in the plurality of first openings.

The first lens may be disposed in the plurality of first openings.

The plurality of first openings may be enclosed by the touch insulating layer.

The side surfaces of the plurality of first openings may be inclined surfaces.

The plurality of touch electrodes may be formed of a material having a light reflection characteristic.

The plurality of touch electrodes may include a light reflection layer which is formed of a material having a light reflection characteristic; and a light absorption layer which is disposed on the light reflection layer and is formed of a material having a light absorption characteristic.

The light absorption layer may include a first layer, a second layer disposed on the first layer, and a third layer disposed on the second layer.

The first layer and the third layer may include niobium pentoxide (Nb2O5) or manganese (Mn) and the second layer may include nickel chrome (NiCr) or alumina (Al2O3).

The plurality of touch electrodes may be formed of a material having a light absorption characteristic.

The first lens and the second lens may be formed by a thermal reflow method.

According to another aspect of the present disclosure, a display device may include a substrate in which a plurality of pixels each including a plurality of sub pixels is disposed; a first light emitting diode and a second light emitting diode disposed in each of the plurality of sub pixels; a touch sensor unit disposed above the first light emitting diode and the second light emitting diode; a plurality of first lenses which is disposed so as to overlap an emission area of the first light emitting diode on the touch sensor unit and has a viewing angle of a first value; and a plurality of second lenses which is disposed so as to overlap an emission area of the second light emitting diode on the touch sensor unit and has a viewing angle of a second value which is higher than the first value.

In the touch sensor unit, a plurality of first openings which overlaps an emission area of the first light emitting diode and a second opening which overlaps an emission area of the second light emitting diode may be disposed, the plurality of first lenses may be disposed so as to correspond to the plurality of first openings, and the second lens may be disposed so as to correspond to the second opening.

One second opening and one second lens may be provided.

A plurality of second openings and a plurality of second lenses may be provided.

The touch sensor unit may include a plurality of bridge electrodes; a touch insulating layer disposed on the plurality of bridge electrodes; and a plurality of touch electrodes which is disposed on the touch insulating layer and is electrically connected to the plurality of bridge electrodes.

The plurality of touch electrodes may be disposed on side surfaces of the plurality of first openings and the second opening in the touch sensor unit.

The plurality of touch electrodes may be formed of a material having a light reflection characteristic.

The plurality of touch electrodes may include a light reflection layer which is formed of a material having a light reflection characteristic; and a light absorption layer which is disposed on the light reflection layer and is formed of a material having a light absorption characteristic.

The plurality of touch electrodes may be formed of a material having a light absorption characteristic.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a pixel on a substrate, the pixel including a plurality of sub pixels representing different colors, each of the plurality of sub pixels including a first light emitting diode and a second light emitting diode;
a touch sensor unit on the first light emitting diode and the second light emitting diode of a sub pixel of the plurality of sub pixels, the touch sensor unit including a plurality of first openings overlapping an emission area of the first light emitting diode of the sub pixel;
a plurality of first lenses disposed within the plurality of first openings of the touch sensor unit, the plurality of first lenses having a viewing angle of a first value and each of the plurality of first lenses overlapping the emission area of the first light emitting diode of the sub pixel; and
a second lens on the touch sensor unit, the second lens has a viewing angle of a second value that is greater than the first value and the second lens overlapping an emission area of the second light emitting diode of the sub pixel.

2. The display device according to claim 1, wherein the touch sensor unit further includes a second opening that overlaps the emission area of the second light emitting diode, and the second lens is disposed within the second opening.

3. The display device according to claim 2, wherein the second opening has an aspect ratio that is larger than an aspect ratio of a first opening from the plurality of first openings.

4. The display device according to claim 1, wherein the plurality of first lenses are arranged in a matrix in the emission area of the first light emitting diode.

5. The display device according to claim 1, wherein the touch sensor unit further comprises:
a plurality of bridge electrodes;
a touch insulating layer on the plurality of bridge electrodes; and
a plurality of touch electrodes on the touch insulating layer, the plurality of touch electrodes electrically connected to the plurality of bridge electrodes, and the plurality of touch electrodes cover side surfaces of the plurality of first openings.

6. The display device according to claim 5, wherein the plurality of touch electrodes and the plurality of bridge electrodes are connected on the side surfaces of the plurality of first openings.

7. The display device according to claim 5, wherein each first lens from the plurality of first lenses is in contact with a corresponding touch electrode from the plurality of touch electrodes in a corresponding first opening from the plurality of first openings.

8. The display device according to claim 5, wherein the plurality of first openings is surrounded by the touch insulating layer.

9. The display device according to claim 5, wherein the side surfaces of the plurality of first openings are inclined surfaces.

10. The display device according to claim 5, wherein the plurality of touch electrodes include a material that reflects light.

11. The display device according to claim 5, wherein the plurality of touch electrodes includes:
a light reflection layer including a material that reflects light; and
a light absorption layer on the light reflection layer, the light absorption layer including a material that absorbs light.

12. The display device according to claim 11, wherein the light absorption layer includes a first layer, a second layer on the first layer, and a third layer on the second layer, the first layer and the third layer include niobium pentoxide (Nb₂O₅) or manganese (Mn) and the second layer includes nickel chrome (NiCr) or alumina (Al₂O₃).

13. The display device according to claim 5, wherein the plurality of touch electrodes include a material that absorbs light.

14. A display device comprising:
a substrate;
a sub-pixel on the substrate, the sub-pixel including a first light emitting diode;
a touch sensor including a plurality of first openings that overlap an emission area of the first light emitting diode; and
a plurality of first lenses on the touch sensor, each first lens from the plurality of first lenses disposed within a corresponding first opening from the plurality of first openings and in contact with a portion of the touch sensor within the corresponding first opening.

15. The display device according to claim 14, wherein the touch sensor further comprises:
a plurality of bridge electrodes;
a touch insulating layer on the plurality of bridge electrodes; and
a plurality of touch electrodes on the touch insulating layer, the plurality of touch electrodes electrically connected to the plurality of bridge electrodes, and a portion of each of the plurality of touch electrodes is disposed within a corresponding first opening from the plurality of first openings.

16. The display device of claim 15, wherein the portion of each of the plurality of touch electrodes is slanted with respect to the plurality of bridge electrodes.

17. The display device of claim 16, wherein each first lens is in direct contact with the slanted portion of a corresponding touch electrode from the plurality of touch electrodes within the corresponding first opening.

18. The display device of claim 16, wherein the sub-pixel further includes a second light emitting diode and the touch sensor further includes a second opening that overlaps an emission area of the second light emitting diode,
wherein a viewing angle of the second lens is greater than a viewing angle of the plurality of first lenses.

19. The display device of claim 18, wherein the first light emitting diode emits light during a privacy mode without the second light emitting diode emitting light during the privacy mode, and the second light emitting diode emits light during a sharing mode without the first light emitting diode emitting light during the sharing mode.

20. The display device according to claim 18, wherein the second opening has an aspect ratio that is larger than an aspect ratio of a first opening from the plurality of first openings.
